(19) United States
(12) Patent Application Publication
(10) Pub. No.: US 2023/0411127 A1
(43) Pub. Date: Dec. 21, 2023

(54) METHODS FOR RETROFITTING AN ETCHING APPARATUS

(71) Applicant: TAIWAN SEMICONDUCTOR MANUFACTURING COMPANY, LTD., Hsinchu (TW)

(72) Inventors: Tai-Jung CHUANG, Taipei City (TW); Chiao-Yuan HSIAO, Hsinchu County (TW); Yung-Chan CHEN, Tainan City (TW); Wei Kang CHUNG, Hsinchu County (TW); Yu-Li LIN, Kaohsiung City (TW); Jui Fu HSIEH, Zhubei City (TW); Chih-Teng LIAO, Hsinchu City (TW)

(21) Appl. No.: 17/842,565

(22) Filed: Jun. 16, 2022

(51) Int. Cl. H01J 37/32; H01L 21/66; H01L 21/311

(52) U.S. Cl. CPC H01J 37/32807; H01J 37/32449; H01L 22/26; H01L 21/31116; H01J 2237/334; H01J 2237/24585

(57) ABSTRACT

Embodiments are directed to a method of operating a plasma processing system by retrofitting one or more components thereof. The method includes removing a holder from a gas supply mechanism of the plasma processing system. The holder includes a gas injector that is configured to provide gas received from a gas source to a plasma chamber of the plasma processing system. The method further includes reducing a size of a guide pin of the holder, installing the holder including the guide pin having the reduced size in the gas supply mechanism, and rotating the gas injector to change a flow of gas through the gas injector.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a fin FET (Fin FET) and a gate-all-around (GAA) FET. In a Fin FET, a gate electrode is adjacent to three side surfaces of a channel region with a gate dielectric layer interposed therebetween. Because the gate structure surrounds (wraps) the fin on three surfaces, the transistor essentially has three gates controlling the current through the fin or channel region. Unfortunately, the fourth side, the bottom part of the channel is far away from the gate electrode and thus is not under close gate control. In contrast, in a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL). As transistor dimensions are continually scaled down to sub 10-15 nm technology nodes, further improvements of the GAA FET are required.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for manufacturing a semiconductor device, according to an embodiment of the present disclosure.

FIGS. 2A, 2B, 2C, 2D, 2E, 2F, and 2G are schematic cross-sectional views of various stages of manufacturing a semiconductor device according to an embodiment of the present disclosure.

FIG. 3 is a schematic view of a plasma processing chamber for manufacturing a semiconductor device.

FIG. 4A illustrates an isometric front view of a gas injector.

FIG. 4B illustrates a plan view of an upper surface of the gas injector of FIG. 4A.

FIG. 4C illustrates a plan view of a bottom surface of the gas injector of FIG. 4A.

FIG. 4D illustrates a cross-sectional view of the gas injector of FIG. 4A.

FIG. 5A illustrates an isometric front view an assembly including a holder having the gas injector installed therein.

FIG. 5B illustrates an isometric view of a bottom portion of the holder.

FIG. 5C illustrates the assembly in FIG. 5A with the holder removed.

FIG. 6A is an isometric view of a weldment positioned over the holder having the gas injector installed therein.

FIG. 6B is a plan view of a bottom surface of the weldment in FIG. 6A.

FIG. 6C is a cross-sectional view of the weldment positioned over the gas injector.

FIG. 6D is a schematic plan view illustrating the offset between the edge feeding hole and the one edge feeding passageway.

FIG. 7 illustrates oxide etch rate map showing radius dependent variation of etch rate.

FIG. 8A illustrates the holder with the guide pin removed.

FIG. 8B is a schematic plan view illustrating the edge feeding hole and the edge feeding passageway substantially coincident relative to their positions in FIG. 6D.

FIG. 9 illustrates an oxide etch rate map showing radius dependent variation of etch rate.

FIG. 10 illustrates the weldment coupled to an actuator.

FIG. 11 is a graph illustrating a variation in the etch rate in the vicinity of the central gas feeding passageway with change in the rotation angle of the weldment or the gas injector.

FIG. 12A is a schematic view of a computer system.

FIG. 12B is a diagram showing an internal configuration of the computer system 1200.

FIG. 13 is a flowchart of a method of operating a plasma processing system by retrofitting one or more components, according to an embodiment of the present disclosure.

FIG. 14 is a method of processing a semiconductor substrate using a plasma processing system, according to an embodiment of the present disclosure.

FIG. 15 is a method of operating a plasma processing system, according to an embodiment of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, a phrase “one of A, B and C” means “A, B and/or C” (A, B, C, A and B, A and C, B and C, or A, B and C), and does not mean one element from A, one element from B and one element from C, unless otherwise described.

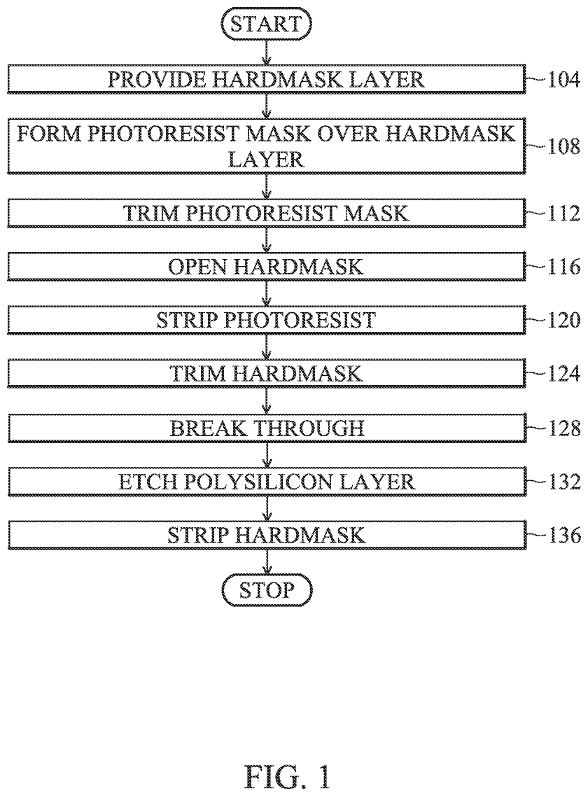

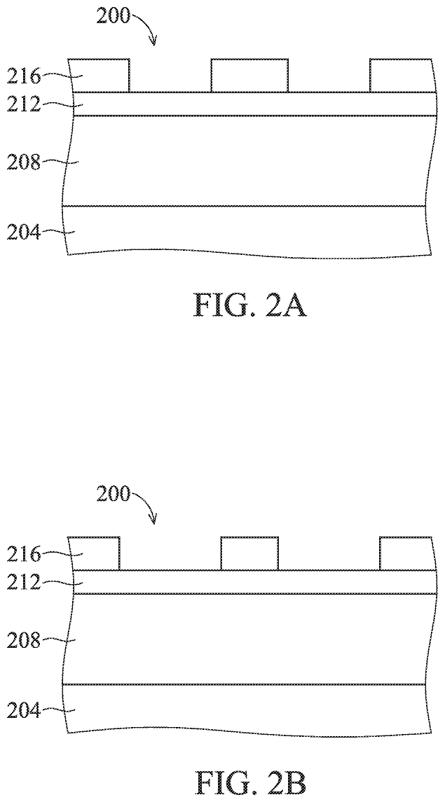

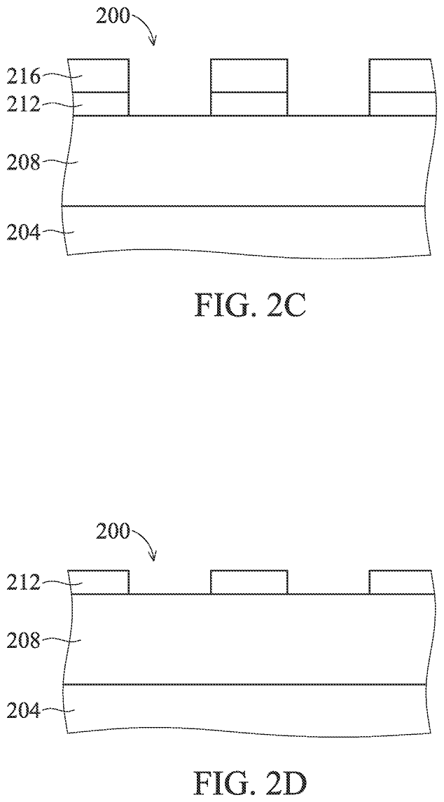

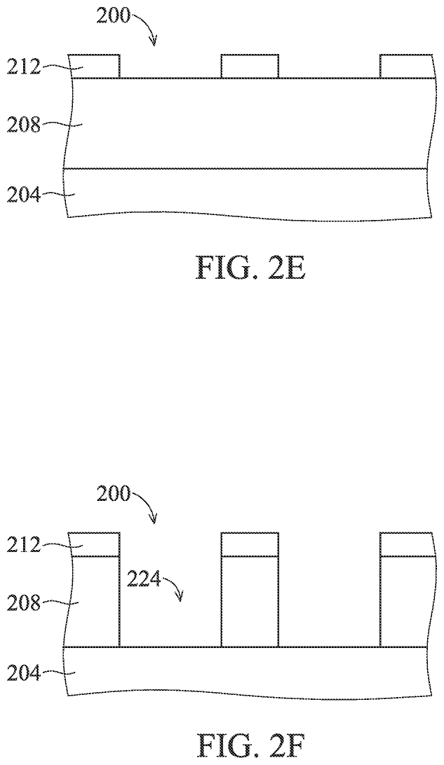

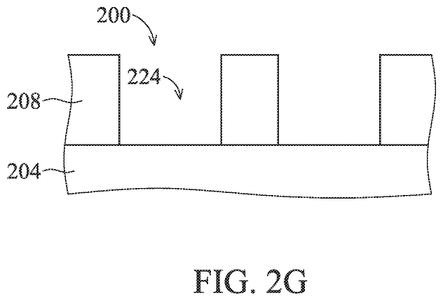

FIG. 1 is a flow chart of a method for manufacturing a semiconductor device, according to an embodiment of the present disclosure. A hard mask layer is provided over a polysilicon layer (step 104). As illustrated in FIG. 2A, a polysilicon layer 208 is formed over a substrate 204, over which a hard mask layer 212 is formed forming a stack 200. In some embodiments, the hard mask layer includes a silicon based hard mask material, which is SiN, silicon rich nitride (SRN), SiO₂, tetraethoxysilane (TEOS), or SiON.

A patterned photoresist mask 216 is formed over the hard mask layer 212 (step 108). In some embodiments, a bottom antireflective coating (BARC) is placed between the photoresist mask 216 and the hard mask layer 212. To provide the patterned mask, a photoresist layer may be first formed over the etch layer. The patterned photoresist mask 216 is trimmed (step 112), as shown in FIG. 2B. The trimming partially reduces the mask to a desired CD. In some embodiments, trimming uses a photoresist trim gas including one or more of O₂, HBr, C₁₂, He, and CF₄.

The hard mask layer 212 is opened forming a patterned hard mask (step 116), as shown in FIG. 2C. The photoresist mask 216 is stripped (step 120), as shown in FIG. 2D. The patterned hard mask formed from the hard mask layer 212 is trimmed (step 124), as shown in FIG. 2E. The trimming operation is performed using a hard mask trim gas. In some embodiments, the hard mask trim gas is carbon free and includes oxygen and a fluorine containing compound. In some embodiments, the flow rate of oxygen is greater than the flow rate of the fluorine containing compound. The hard mask trim gas is formed into a plasma. The plasma trims the hard mask and provides an infinite selectivity with respect to polysilicon. In some embodiments, a break through step (step 128) is provided to complete the formation of features in the hard mask layers 212. In some other embodiments, the break through step is omitted.

The polysilicon layer 208 is etched through the hard mask (step 132) to form features 224, as shown in FIG. 2F. The hard mask may then be stripped (step 136), as shown in FIG. 2G. Whether a hard mask strip is needed is dependent upon the specific gate application. In some embodiments, the hard mask strip operation is omitted.

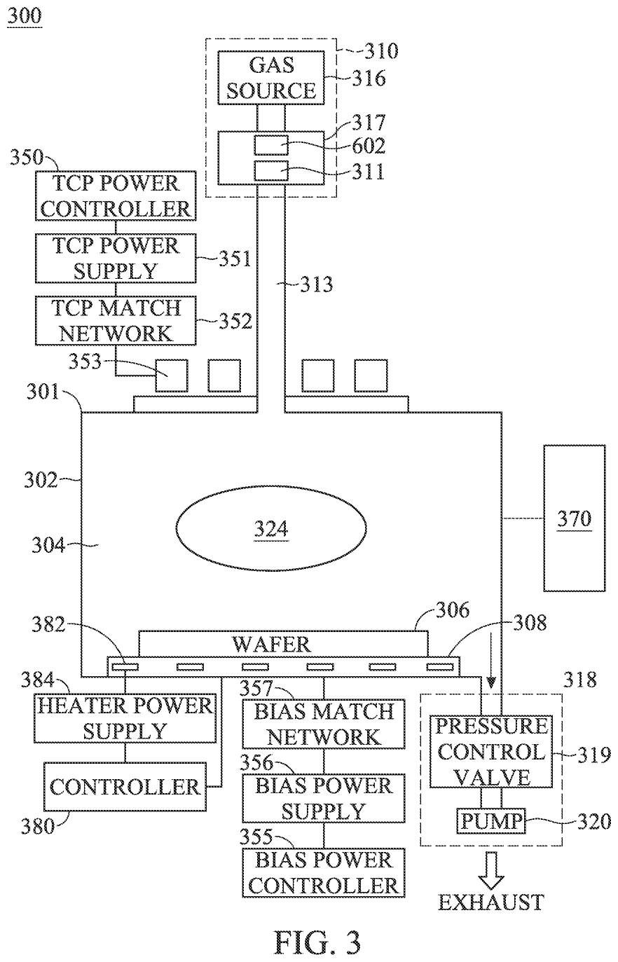

FIG. 3 is a schematic view of a plasma processing system 300, including a plasma processing tool 301. The plasma processing tool 301 is an inductively coupled plasma etching tool and includes a plasma reactor 302 having a plasma chamber 304 therein. A transformer coupled power (TCP) controller 350 and a bias power controller 355, respectively, control a TCP power supply 351 and a bias power supply 356 influencing the plasma 324 created within plasma chamber 304.

The TCP power controller 350 sets a set point for TCP power supply 351 configured to supply a radio frequency signal at 13.56 MHz, tuned by a TCP match network 352, to a TCP coil 353 located near the plasma chamber 304. An RF transparent window 354 is provided to separate TCP coil 353 from plasma chamber 304 while allowing energy to pass from TCP coil 353 to plasma chamber 304. An optically transparent window 365 is provided by a circular piece of sapphire having a diameter of approximately 2.5 cm (1 inch) located in an aperture in the RF transparent window 354.

The bias power controller 355 sets a set point for bias power supply 356 configured to supply an RF signal, tuned by bias match network 357, to a chuck electrode 308 located within the plasma chamber 304 creating a direct current (DC) bias above chuck electrode 308 which is adapted to receive a substrate 306, such as a semi-conductor wafer work piece, being processed.

A gas supply mechanism or gas source 310 includes one or more gas sources 316 attached via a gas manifold 317 to supply the proper chemistry required for the process to the interior of the plasma chamber 304. The gas manifold 317 includes a gas injector 311 for directing the gas from the one or more gas sources 316 into the plasma chamber 304 through the flow path 313. Although, the gas injector 311 is illustrated as being located inside the gas manifold 317, the gas injector 311 can be located in the flow path 313.

A gas exhaust mechanism 318 includes a pressure control valve 319 and exhaust pump 320 and removes particles from within the plasma chamber 304 and maintains a particular pressure within plasma chamber 304.

A temperature controller 380 controls the temperature of heaters 382 provided within the chuck electrode 308 by controlling a heater power supply 384. The plasma processing system 300 also includes electronic control circuitry 370 for controlling an overall operation of the plasma processing system 300.

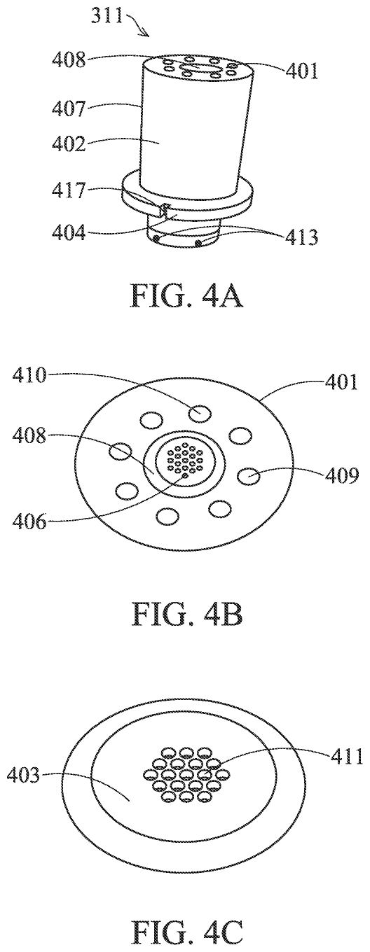

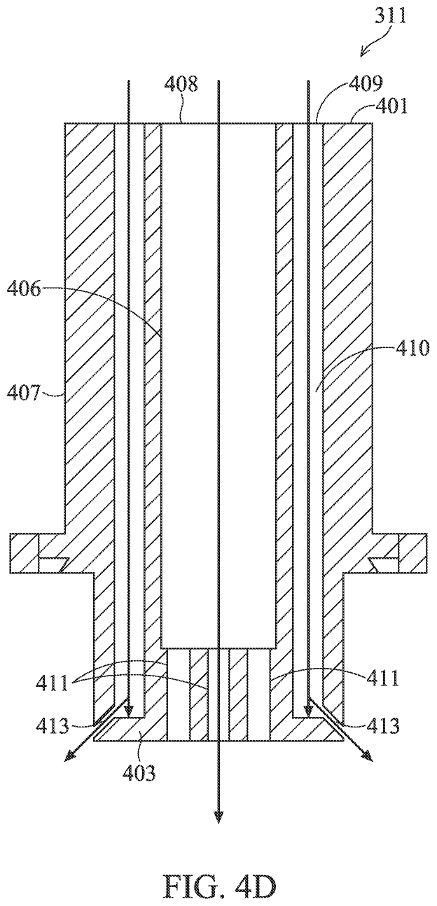

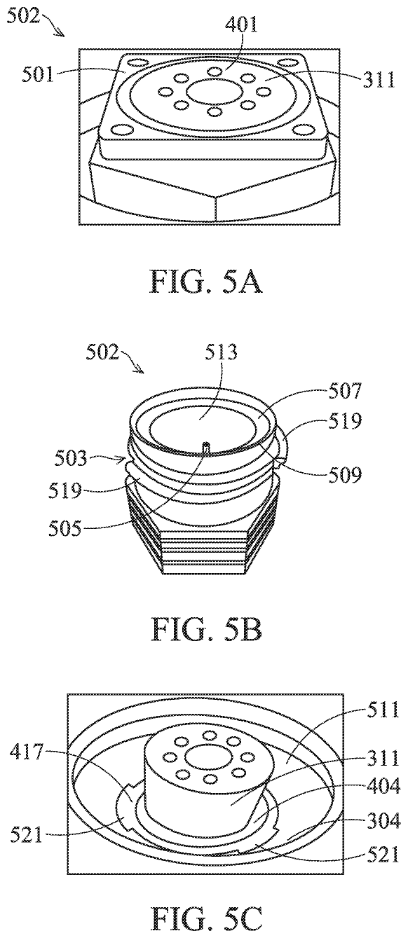

FIG. 4A illustrates an isometric front view of the gas injector 311. FIG. 4B illustrates a plan view of an upper or top surface 401 of the gas injector 311 of FIG. 4A. FIG. 4C illustrates a plan view of a bottom surface 403 of the gas injector 311 of FIG. 4A. FIG. 4D illustrates a cross-sectional view of the gas injector 311 of FIG. 4A. Referring to FIG. 4A, the gas injector 311 has a cylindrical body 402 extending longitudinally and including a circular flange 404 on the outer surface 407 of the body 402. As illustrated, the flange 404 is longitudinally offset from the center of the body 402. However, the flange 404 can be located at any longitudinal position along the outer surface 407 of the body 402. The flange 404 defines a notch (or indentation) 417 on the outer circumferential edge of the flange 404. As discussed below, the notch 417 accommodates a guide pin 505 shown in FIG. 5B. The body 402 includes a central gas feeding passageway 406 that extends longitudinally in the body 402 from the upper surface 401 of the body 402 to the bottom surface 403 of the body 402. An opening 408 (also referred to as a central opening) of the central gas feeding passageway 406 is located centrally on the upper surface 401. A diameter of the central gas feeding passageway 406 is around 12.7 mm (around 0.5 inch).

The body 402 further includes a plurality of edge feeding passageways or holes 410 located concentrically about the central gas feeding passageway 406. Each edge feeding passageway 410 extends longitudinally in the body 402 between the upper surface 401 of the body 402 and the bottom surface 403 of the body 402. A plurality of peripheral openings 409 each corresponding to an edge feeding passageway 410 are located on the upper surface 401 and about the central opening 408 of the central gas feeding passageway 406. The edge feeding passageways 410 are arranged spaced from each other at regular intervals about the central gas feeding passageway 406.

The central gas feeding passageway 406 opens on the bottom surface 403 via a plurality of outlet holes 411 as shown in FIGS. 4C and 4D. The plurality of outlet holes 411 are all located within the diameter of the central gas feeding passageway 406. The plurality of outlet holes 411 are arranged in a desired pattern on the bottom surface 403. As illustrated in FIG. 4C, the plurality of outlet hole 411 are arranged in a hexagonal pattern, but any desired pattern is possible. Referring to FIGS. 4A and 4D, each edge feeding passageway 410 opens on the outer surface 407 of the body 402 proximate the bottom surface 403 via edge feeding outlets 413. As illustrated, the edge feeding outlets 413 are located along the bottom rim of the body 402.

In the plasma processing system 300, the gas injector 311 is located in a holder, and assembly including the holder having the gas injector 311 is installed in the gas manifold 317. When installed, the portion of the body 402 of the gas injector 311 below the flange 404 (see FIG. 4A) is received in the plasma chamber 304 such that the gas flowing through the gas injector 311 is provided to the plasma chamber 304.

FIG. 5A illustrates an isometric front view an assembly including a holder 502 having the gas injector 311 installed therein. FIG. 5B illustrates an isometric view of a bottom portion 503 of the holder 502. Referring to FIGS. 5A and 5B, the holder 502 includes a central through-hole (or opening) 513 that is sized, shaped (or otherwise configured) to receive the gas injector 311 therein. The gas injector 311 is received substantially within the central through-hole 513 and the upper surface 401 of the gas injector 311 is flush with the upper surface 501 of the holder 502. The holder 502 includes a guide pin 505 that is located on the bottom portion 503. As illustrated, the guide pin 505 is located on a bottom peripheral surface 507 that defines (at least partially) the bottom portion 503 of the holder 502. The guide pin 505 extends axially from the bottom peripheral surface 507 and protrudes a certain distance away from the bottom edge (or bottom rim) 509 of the bottom portion 503.

FIG. 5C illustrates the assembly in FIG. 5A with the holder 502 removed. In FIG. the bottom portion of the body 402 of the gas injector 311 is not visible since it is located in the plasma chamber 304. The flange 404 rests on the upper surface 511 of the plasma chamber 304. The notch 417 receives the guide pin 505 when the holder 502 receives the gas injector 311. Inserting the guide pin 505 in the notch 417 limits angular (or rotational) displacement of the gas injector 311 and holder 502 and thereby maintains a correct alignment of the gas injector 311 with a weldment used for injecting gas into the gas injector 311, as discussed below.

The outer surface of the holder 502 includes protrusions or “teeth” 519 that are received into corresponding slots 521 in upper surface 511 of the plasma chamber 304. As a result, the holder 502 is restricted from rotating when installed on the plasma chamber 304.

The gas is provided to the gas injector 311 via an adapter, also referred to as a weldment, that injects gas into the gas injector 311. The weldment is installed on the holder 502 and is in fluid communication with gas injector 311. The weldment includes two openings, one for directing gas to the central gas feeding passageway 406 and another for providing gas to all the edge feeding passageways 410. The gas flows from the central gas feeding passageway 406 and the edge feeding passageways 410 to the plasma chamber 304.

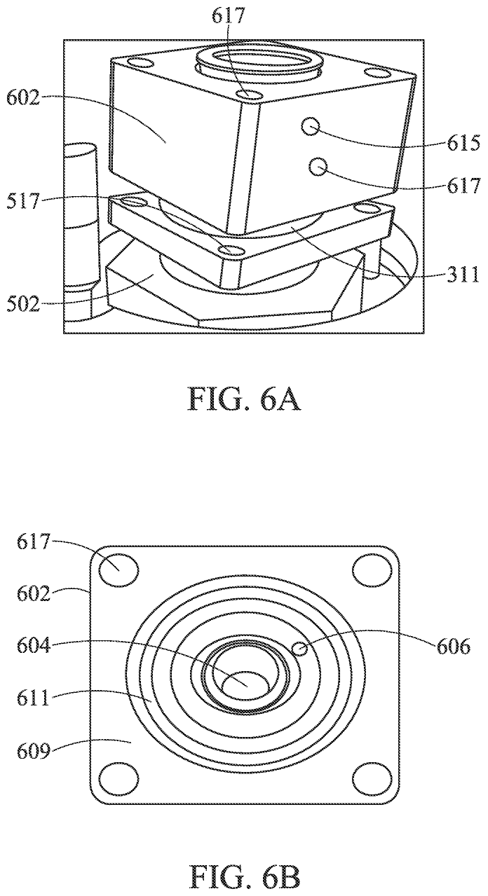

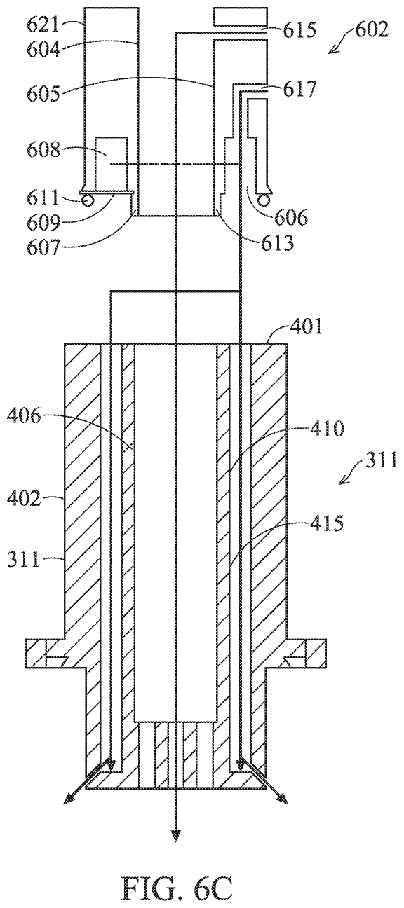

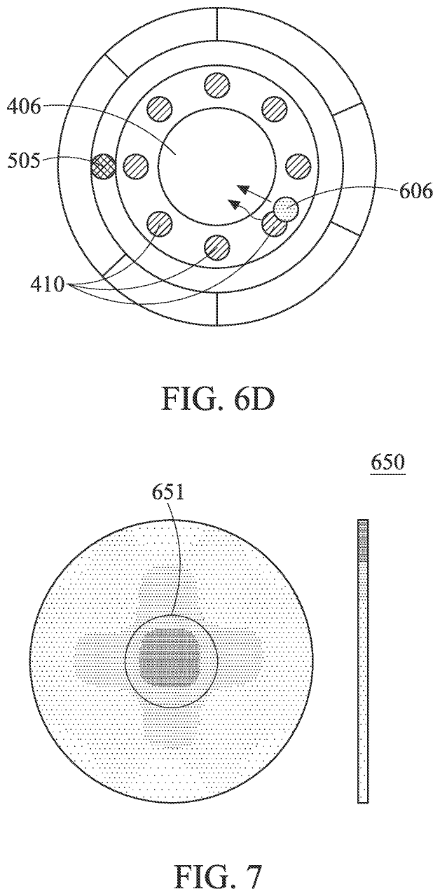

FIG. 6A is an isometric view of a weldment 602 positioned over the holder 502 having the gas injector 311 installed therein. It should be noted that, in the position illustrated in FIG. 6A, the guide pin 505 of the holder 502 is located in the notch 417 to limit the angular displacement of the holder 502. The weldment 602 is coupled to the holder 502 using fasteners that are received in the corresponding openings 517 in the holder 502 and openings 617 in the weldment 602. The weldment 602 includes openings for the first channel 615 and the second channel 617 on the outer surface 621 thereof for receiving gas to be provided to the central gas feeding passageway 406 and gas to be provided to the edge feeding passageways 410, respectively.

FIG. 6B is a plan view of a bottom surface 609 of the weldment 602. FIG. 6C is a cross-sectional view of the weldment 602 positioned over the gas injector 311. For the sake of explanation, the weldment 602 is shown as vertically separated from the gas injector 311, and the holder 502 is omitted. Referring to FIGS. 6B and 6C, as illustrated, the weldment 602 includes a central feeding hole 604 defined by inner sidewalls 605 and an edge feeding hole 606 located radially separated (outward) from the central feeding hole 604. The weldment 602 includes an annular chamber (or space) 608 surrounding the central feeding hole 604 and isolated therefrom. The weldment 602 also includes a first channel 615 that opens on the outer surface 621 of the weldment 602 and is fluidly coupled to the central feeding hole 604, and a second channel 617 that opens on the outer surface 621 of the weldment 602 and is fluidly coupled to the annular chamber 608. The annular chamber 608 fluidly couples the second channel 617 with the edge feeding hole 606.

The central feeding hole 604 extends into a central protrusion 607 that extends a certain distance away from the bottom surface 609 of the weldment 602. When the weldment 602 is installed on the holder 502, the bottom surface 609 contacts the upper surface 401 of the body 402 of the gas injector 311 and the central protrusion 607 is received within the central gas feeding passageway 406. The central protrusion 607 extends around 3 mm into the central gas feeding passageway 406. When the weldment 602 is installed on the holder 502, a gap is defined between the upper surface 401 of the body 402 of the gas injector 311 and the bottom surface 609 of the weldment 602. During operation, with the weldment 602 installed, gas injected via the first channel 615 flows into the central gas feeding passageway 406 of the gas injector 311 via the central feeding hole 604, and gas injected via the second channel 617 flows into all the edge feeding passageways 410 via the annular chamber 618 and the gap. A sealing element 611 (e.g., an O-ring) is located about edge feeding passageways 410 and the edge feeding hole 606 to limit the gas flowing into the gap from leaking to the outside.

When the weldment 602 is installed on the holder 502, the edge feeding hole 606 overlaps one of the plurality of edge feeding passageways 410 of the gas injector 311. However, while the edge feeding hole 606 overlaps the one of the plurality of edge feeding passageways 410 of the gas injector 311, the edge feeding hole 606 and the one edge feeding passageway 410 are not coincident. In other words, the edge feeding hole 606 and the one edge feeding passageway 410 do not completely overlap. This mismatch in overlap is because of the way the gas injector 311 and the weldment 602 manufactured and the manner in which the gas injector 311 and the weldment 602 are coupled to each other.

FIG. 6D is a schematic plan view illustrating the offset between the edge feeding hole 606 and the one edge feeding passageway 410. As illustrated, the edge feeding hole 606 does not completely overlap the edge feeding passageway 410. As a result of this offset, a small amount of gas flows through the edge feeding hole 606 seeps into the central gas feeding passageway 406 of the gas injector 311, as indicated by the arrows. This is because, there is a gap (tolerance) between the outer wall 613 of central protrusion 607 and the inner wall 415 of the central gas feeding passageway 406 when the central protrusion 607 is received within the central gas feeding passageway 406. The gas seeps into the central gas feeding passageway 406 through the gaps.

This seepage increases the gas flowing through the central gas feeding passageway 406, since there is already gas flowing into the central gas feeding passageway 406 from the central feeding hole 604. Because of an increased amount of gas flowing through the central gas feeding passageway 406, the etching rate caused by the gas flow through the central gas feeding passageway 406 increases compared to the etching rate caused by the gas flowing through the edge feeding passageways 410.

FIG. 7 illustrates oxide etch rate map 750 showing radius dependent variation of etch rate. As illustrated, in the map 750, the center of wafer loses more surface material due to higher etch rate caused by the increased gas flow through the central gas feeding passageway 406. The higher etch rate is indicated by the encircle region 751. It would be beneficial to limit the gas flow through the central gas feeding passageway 406 to obtain a more uniform etch rate. For example, the oxide etch rate map 750 is indicative of the etching rate of the hard mask layer 212 in operation illustrated in FIG. 2F. The encircled region 751 is indicative of the hard mask layer 212 in the center being etched at a higher rate than the two outlying hard mask layers 212.

Embodiments of the disclosure are directed to retrofitting the gas supply mechanism of the plasma processing system with a holder that does not include the guide pin. According to embodiments, the retrofitting includes reducing a size of the guide pin of the holder and installing the holder having the reduced size guide pin in the gas supply mechanism. The weldment is positioned over the holder. The holder (including the gas injector) is rotated in a counterclockwise direction. The weldment is rotated in a clockwise direction in order to substantially align (coincide) the edge feeding hole with one of the plurality of edge feeding passageways. By removing the guide pin, the gas injector and the holder can be rotated together. As a result, the flow of gas between the edge feeding hole 606 and the edge feeding passageway 410 is not impeded and seepage of the gas into the central gas feeding passageway 406 is substantially reduced. Since the gas flowing through the central gas feeding passageway 406 does not increase, a uniform etch rate is obtained. In some embodiments, the holder (including the gas injector) is rotated about 1° to 3° in a counterclockwise direction relative to the original position of the holder, and the weldment is rotated about 1° to 3° in a clockwise direction relative to the original position of the weldment. In some embodiments, the holder (including the gas injector) is rotated about 2° in a counterclockwise direction relative to the original position of the holder, and the weldment is rotated about 2° in a clockwise direction relative to the original position of the weldment.

In some embodiments, the weldment is rotated using an actuator attached thereto. In other embodiments, a new gas injector can be manufactured in which the edge feeding passageways 410 are rotated about 2° in a counterclockwise direction relative to the existing gas injector 311.

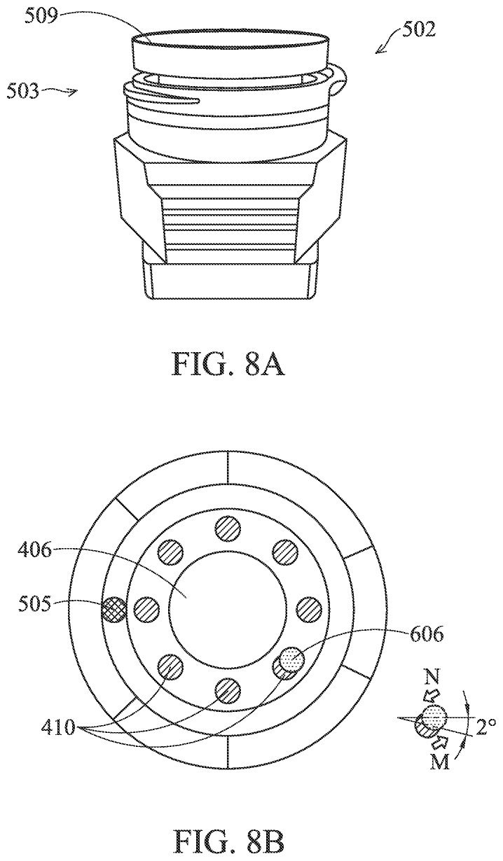

FIG. 8A illustrates the holder 502 with the guide pin 505 removed. In some embodiments, the guide pin 505 is not completely removed, but shaved (or trimmed) such that the guide pin 505 does not extend into the notch 417. Once the guide pin 505 is removed (or shaved), the gas injector 311 can be rotated. As discussed above, in some embodiments, the gas injector is rotated about 2° in a counterclockwise direction.

FIG. 8B is a schematic plan view illustrating the edge feeding hole 606 and the edge feeding passageway 410 substantially coincident relative to their positions in FIG. 6D. The positions of the edge feeding hole 606 and the edge feeding passageway 410 are obtained by rotating the holder 502 (including the gas injector 311) by around 2° in a counterclockwise direction (indicated by arrow M) and rotating the weldment 602 by around 2° in a clockwise direction (indicated by arrow N). In some embodiments, the gas injector 311 and the weldment 602, and thereby the edge feeding hole 606 and the edge feeding passageway 410, are rotated sequentially. In some embodiments, the gas injector 311 and the weldment 602, and thereby the edge feeding hole 606 and the edge feeding passageway 410, are rotated simultaneously. The angle by which the gas injector 311 and the weldment 602 are rotated is not limited to 2°. In some embodiments, the gas injector 311 and the weldment 602 are rotated by 1°, as required by the application. In some embodiments, the gas injector 311 and the weldment 602 are rotated by angles greater than 2°, as required by the application. After the gas injector 311 and the weldment 602 are rotated, the weldment 602 is coupled to the holder 502 using fasteners. It should be noted that even when rotated, the weldment 602 can be coupled to the holder 502 since there is an amount of tolerance that permits the fasteners to be received in the corresponding openings 517 in the holder 502 and openings 617 in the weldment 602.

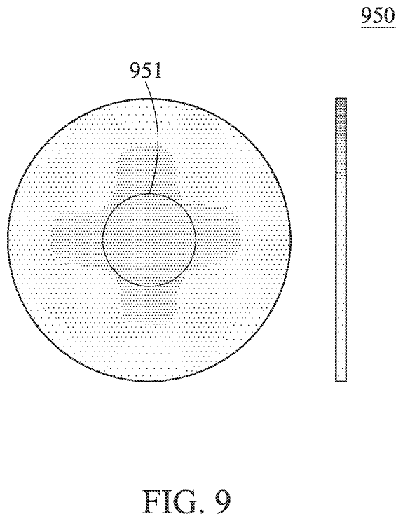

FIG. 9 illustrates an oxide etch rate map 950 showing radius dependent variation of etch rate. As illustrated, in the map 950, and unlike as illustrated in FIG. 7, the center of wafer 951 does not lose more surface material than the peripheral potions of the wafer since the etch rate has been reduced by decreasing the gas flow through the central gas feeding passageway 406 using the aspects of embodiments disclosed herein. For example, the oxide etch rate map 950 is indicative of the etching rate of the hard mask layer 212 in operation illustrated in FIG. 2F after the gas supply mechanism 310 of the plasma processing system 300 has been retrofitted according to the embodiments of the disclosure. The encircled region 951 is indicative of the hard mask layer 212 in the center being etched at a lower rate compared to the rate in FIG. 8. As a result, the wafer is subjected to a more uniform etching operation.

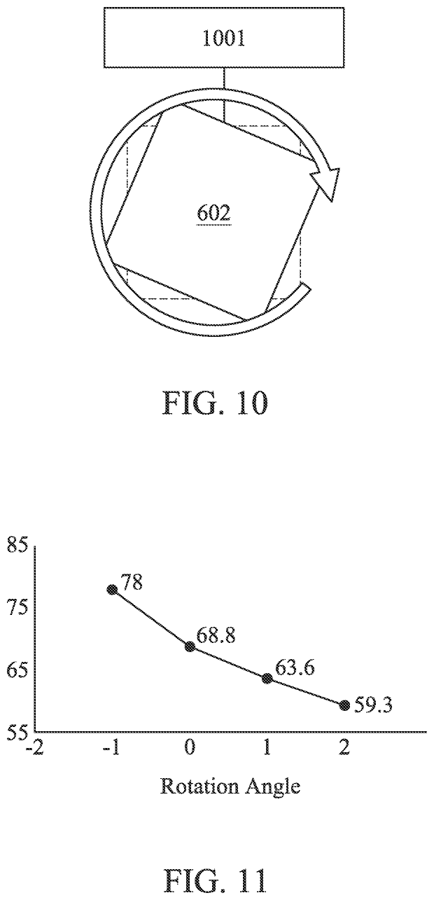

In some embodiments, the weldment 602 is coupled to an actuator for controlling the rotational motion of the weldment 602. FIG. 10 illustrates the weldment 602 coupled to an actuator 1001. In some embodiments, the actuator 1001 is a stepper motor. However, embodiments are not limited to stepper motors or any specific kind of actuating device. Any other types of actuating devices such as mechanical actuators, hydraulic actuators, pneumatic actuators, linear actuators, rotary actuators, electromechanical actuators, electrohydraulic actuators, thermal actuators, magnetic actuators, can be used to rotate the weldment 602, without departing from the scope of the disclosure. As illustrated, the weldment 602 was initially in the position indicated by the dashed lines and was rotated clockwise to the new position indicated by the solid lines.

FIG. 11 is a graph 1100 illustrating a variation in the etch rate in the vicinity of the central gas feeding passageway 406 with change in the rotation angle of the weldment 602 or the gas injector 311. As illustrated, the etch rate in the vicinity of the central gas feeding passageway 406 reduces with increase in the rotation angle. The etch rate substantially reduces with increase in the rotation angle and is the least at about 2° rotation angle. Because of the reduction in the etching rate, a more uniform etch profile is obtained, as in FIG. 9.

In some other embodiments, instead of removing the guide pin and rotating the gas injector 311 counterclockwise and the weldment 602 clockwise to align the edge feeding hole 606 with one of the plurality of edge feeding passageways 410, a new gas injector is manufactured that includes the plurality of edge feeding passageways rotated counterclockwise by 2° relative to the plurality of edge feeding passageways 410 in the old gas injector 311.

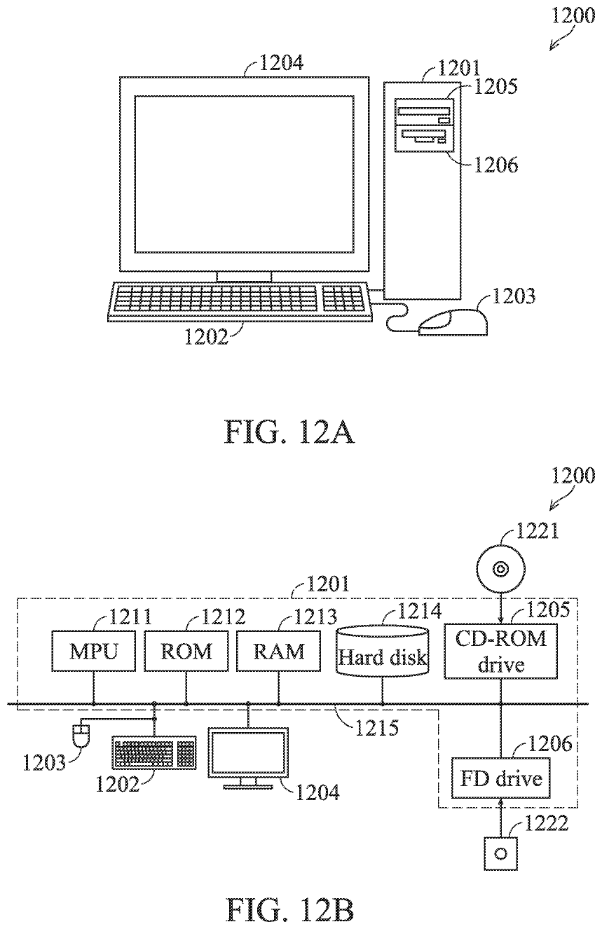

FIG. 12A is a schematic view of a computer system that operates as a controller (e.g., electronic control circuitry 370) for controlling an operation of the plasma processing system 300 and performing other tasks mentioned in the disclosure. The foregoing embodiments may be realized using computer hardware and computer programs executed thereon. In FIG. 12A, a computer system 1200 is provided with a computer 1201 including an optical disk read only memory (e.g., CD-ROM or DVD-ROM) drive 1205 and a magnetic disk drive 1206, a keyboard 1202, a mouse 1203, and a display 1204.

FIG. 12B is a diagram showing an internal configuration of the computer system 1200. In FIG. 12B, the computer 1201 is provided with, in addition to the optical disk drive 1205 and the magnetic disk drive 1206, one or more processors 1211, such as a micro processing unit (MPU), a ROM 1212 in which a program such as a boot up program is stored, a random access memory (RAM) 1213 that is connected to the MPU 1211 and in which a command of an application program is temporarily stored and a temporary storage area is provided, a hard disk 1214 in which an application program, a system program, and data are stored, and a bus 1215 that connects the MPU 1211, the ROM 1212, and the like. Note that the computer 1201 may include a network card (not shown) for providing a connection to a LAN.

The program code for causing the computer system 1200 to execute the operations/tasks discussed in the foregoing embodiments may be stored in an optical disk 1221 or a magnetic disk 1222, which are inserted into the optical disk drive 1205 or the magnetic disk drive 1206, and transmitted to the hard disk 1214. Alternatively, the program may be transmitted via a network (not shown) to the computer 1201 and stored in the hard disk 1214. At the time of execution, the program is loaded into the RAM 1213. The program may be loaded from the optical disk 1221 or the magnetic disk 1222, or directly from a network.

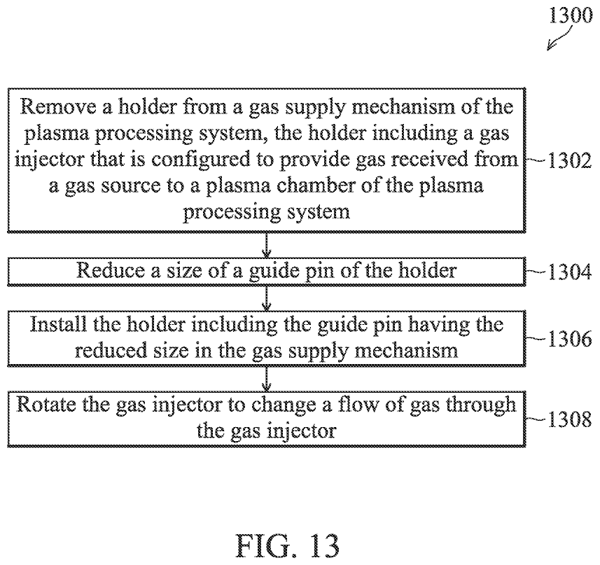

An embodiment of the present disclosure is a method 1300 of operating a plasma processing system by retrofitting one or more components thereof according to the flowchart illustrated in FIG. 13. It is understood that additional operations can be provided before, during, and after processes discussed in FIG. 13, and some of the operations described below can be replaced or eliminated, for additional embodiments of the method. The order of the operations/processes may be interchangeable and at least some of the operations/processes may be performed in a different sequence. At least two or more operations/processes may be performed overlapping in time, or almost simultaneously.

The method includes an operation 1302 of removing a holder from a gas supply mechanism of the plasma processing system, the holder including a gas injector that is configured to provide gas received from a gas source to a plasma chamber of the plasma processing system. In operation 1304, a size of a guide pin of the holder is reduced. In operation 1306, the holder including the guide pin having the reduced size is installed in the gas supply mechanism. In operation 1308, the gas injector is rotated to change a flow of gas through the gas injector.

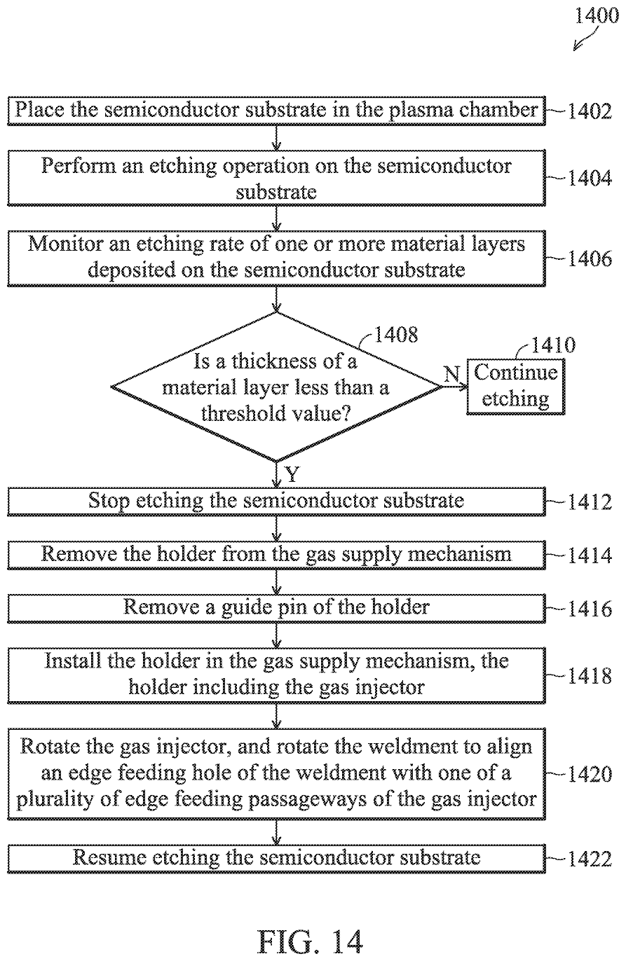

An embodiment of the present disclosure is a method 1400 of processing a semiconductor substrate using a plasma processing system according to the flowchart illustrated in FIG. 14. The plasma processing system includes a plasma chamber and a gas supply mechanism for supplying gas to the plasma chamber via a gas injector installed in a holder and a weldment installed on the gas injector. It is understood that additional operations can be provided before, during, and after processes discussed in FIG. 14, and some of the operations described below can be replaced or eliminated, for additional embodiments of the method. The order of the operations/processes may be interchangeable and at least some of the operations/processes may be performed in a different sequence. At least two or more operations/processes may be performed overlapping in time, or almost simultaneously.

The method includes an operation 1402 of placing the semiconductor substrate in the plasma chamber. In operation 1404, an etching operation is performed on the semiconductor substrate. In operation 1406, an etching rate of one or more material layers deposited on the semiconductor substrate is monitored. Operation 1408 checks if a thickness of a material layer less than a threshold value. If the thickness is not less, then the method continues to operation 1410 wherein the etching is continued. If the thickness is greater, then the method continues to operation 1412 in which the processing of the semiconductor substrate is stopped. Then, in operation 1414, the holder is removed from the gas supply mechanism In operation 1416, a guide pin of the holder is removed. In operation 1418, the holder is installed in the gas supply mechanism having the gas injector included therein. In operation 1420, the gas injector is rotated, and the weldment is rotated to align an edge feeding hole of the weldment with one of a plurality of edge feeding passageways of the gas injector. In operation 1422, the processing of the semiconductor substrate is resumed.

An embodiment of the present disclosure is a method 1500 of operating a plasma processing system according to the flowchart illustrated in FIG. 15. It is understood that additional operations can be provided before, during, and after processes discussed in FIG. 15, and some of the operations described below can be replaced or eliminated, for additional embodiments of the method. The order of the operations/processes may be interchangeable and at least some of the operations/processes may be performed in a different sequence. At least two or more operations/processes may be performed overlapping in time, or almost simultaneously.

The method includes an operation 1502 of placing a semiconductor substrate in a plasma chamber of the plasma processing system. In operation 1504, gas is introduced into the plasma chamber using a gas supply mechanism connected to the plasma chamber. The gas supply mechanism includes one or more sources of gas, a holder including a gas injector, the holder having a guide pin protruding from a bottom surface thereof, the gas injector having a body that has a central gas feeding passageway and a plurality of edge feeding passageways concentrically arranged about the central gas feeding passageway and radially spaced therefrom, and the body having a flange on an outer circumferential surface of the body, the flange including a notch for receiving the guide pin, and a weldment fluidly coupled to the gas injector, the weldment including a central feeding hole and an edge feeding hole located radially separated from the central feeding hole. In operation 1506, one or more layers deposited on the semiconductor substrate are etched. In operation 1508, the etching is stopped. In operation 1510, the holder is removed from the gas supply mechanism. In operation 1512, the guide pin from the holder is removed. In operation 1514, the holder is installed in the gas supply mechanism with the gas injector included therein. In operation 1516, the gas injector is rotated counterclockwise. In operation 1518, the weldment is rotated clockwise. In operation 1520, the etching is resumed.

Embodiments of the disclosure provide an advantageous method of improving the etch rate across the semiconductor substrate using existing apparatus, and thereby being cost-effective.

It will be understood that not all advantages have been necessarily discussed herein, no particular advantage is required for all embodiments or examples, and other embodiments or examples may offer different advantages.

Embodiments of the present disclosure are directed to a method of operating a plasma processing system by retrofitting one or more components thereof. The method includes removing a holder from a gas supply mechanism of the plasma processing system, the holder including a gas injector that is configured to provide gas received from a gas source to a plasma chamber of the plasma processing system, reducing a size of a guide pin of the holder, installing the holder including the guide pin having the reduced size in the gas supply mechanism, and rotating the gas injector to change a flow of gas through the gas injector. In some embodiments, the holder and the gas injector are rotated at least 2° in a counterclockwise direction. In some embodiments, wherein the method further includes removing a weldment installed on the holder before removing the holder, wherein the weldment is installed on the holder such that gas from the gas source flows through the weldment prior to entering the gas injector, after installing the holder, reinstalling the weldment on the holder, and changing the flow of gas through the gas injector by rotating the weldment. In some embodiments, the gas injector is rotated at least 2° in a counterclockwise direction. In some embodiments, the weldment is rotated at least 2° in a clockwise direction. In some embodiments, the gas injector and the weldment are rotated simultaneously. In some embodiments, the gas injector and the weldment are rotated sequentially. In some embodiments, the gas injector includes a central gas feeding passageway that is located centrally in the gas injector and a plurality of edge feeding passageways located concentrically about the central gas feeding hole, and rotating the gas injector to change the flow of gas through the gas injector includes reducing a flow of gas into the central gas feeding hole, the flow of gas intended for flowing through the plurality of edge feeding passageways into the plasma chamber. In some embodiments, the weldment includes a central feeding hole and an edge feeding hole radially offset from the central feeding hole, and the method further includes changing the flow of gas through the gas injector by rotating the weldment such that the edge feeding hole is aligned with one of the plurality of edge feeding passageways, and flow of gas from the edge feeding hole into the central gas feeding passageway is reduced. In some embodiments, reducing the size of the guide pin includes trimming the guide pin such that the guide pin does not extend beyond a bottom edge of the holder. In some embodiments, reducing the size of the guide pin includes removing the guide pin from the holder.

Embodiments of the present disclosure are directed to a method of processing a semiconductor substrate using a plasma processing system, the plasma processing system including a plasma chamber and a gas supply mechanism for supplying gas to the plasma chamber via a gas injector installed in a holder and a weldment installed on the gas injector. The method includes placing the semiconductor substrate in the plasma chamber, performing an etching operation on the semiconductor substrate, and monitoring an etching rate of one or more material layers deposited on the semiconductor substrate. When a thickness of a material layer less than a threshold value, the method includes stopping the processing of the semiconductor substrate, removing the holder from the gas supply mechanism, installing the holder in the gas supply mechanism, the holder including the gas injector, and rotating the gas injector, and rotating the weldment to align an edge feeding hole of the weldment with one of a plurality of edge feeding passageways of the gas injector. The method further includes restarting the processing of the semiconductor substrate. In some embodiments, the gas injector is rotated at least 2° in a first direction, and the weldment is rotated at least 2° in a second direction opposite to the first direction. In some embodiments, a guide pin of the holder is removed after removing the holder from the gas supply mechanism. In some embodiments, aligning the edge feeding hole of the weldment with one of a plurality of edge feeding passageways of the gas injector limits gas flowing through the edge feeding hole from entering a central gas feeding passageway of the gas injector. In some embodiments, the weldment is rotated using a stepper motor. In some embodiments, the gas injector and the weldment are rotated simultaneously. In some embodiments, the gas injector and the weldment are rotated sequentially.

Embodiments of the present disclosure are directed to a method of operating a plasma processing system. The method includes placing a semiconductor substrate in a plasma chamber of the plasma processing system, and introducing gas into the plasma chamber using a gas supply mechanism connected to the plasma chamber. The gas supply mechanism includes one or more sources of gas, a holder including a gas injector, and having a guide pin protruding from a bottom surface thereof, the gas injector has a body having a central gas feeding passageway and a plurality of edge feeding passageways are concentrically arranged about the central gas feeding passageway and radially spaced therefrom, and the body has a flange on an outer circumferential surface of the body and includes a notch for receiving the guide pin, and a weldment fluidly coupled to the gas injector and including a central feeding hole and an edge feeding hole located radially separated from the central feeding hole. The method further includes etching one or more layers deposited on the semiconductor substrate, stopping the etching, removing the holder from the gas supply mechanism, removing the guide pin from the holder, installing the holder in the gas supply mechanism with the gas injector included therein, rotating the gas injector counterclockwise, rotating the weldment clockwise, and resuming the etching. In some embodiments, the gas injector and the weldment are rotated at least 2°.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of operating a plasma processing system by retrofitting one or more components thereof, the method comprising:
removing a holder from a gas supply mechanism of the plasma processing system, the holder including a gas injector that is configured to provide gas received from a gas source to a plasma chamber of the plasma processing system;
reducing a size of a guide pin of the holder;
installing the holder including the guide pin having the reduced size in the gas supply mechanism; and
rotating the gas injector to change a flow of gas through the gas injector.

2. The method of claim 1, wherein the gas injector is rotated at least 2° in a counterclockwise direction.

3. The method of claim 1, wherein the method further comprises:
removing a weldment installed on the holder before removing the holder, wherein the weldment is installed on the holder such that gas from the gas source flows through the weldment prior to entering the gas injector;
after installing the holder, reinstalling the weldment on the holder; and
changing the flow of gas through the gas injector by rotating the weldment.

4. The method of claim 3, wherein the gas injector is rotated at least 2° in a counterclockwise direction.

5. The method of claim 4, wherein the weldment is rotated at least 2° in a clockwise direction.

6. The method of claim 3, wherein the gas injector and the weldment are rotated simultaneously.

7. The method of claim 3, wherein the gas injector and the weldment are rotated sequentially.

8. The method of claim 3, wherein the gas injector includes a central gas feeding passageway that is located centrally in the gas injector and a plurality of edge feeding passageways located concentrically about the central gas feeding hole, and
rotating the gas injector to change the flow of gas through the gas injector includes reducing a flow of gas into the central gas feeding hole, the flow of gas intended for flowing through the plurality of edge feeding passageways into the plasma chamber.

9. The method of claim 8, wherein the weldment includes a central feeding hole and an edge feeding hole radially offset from the central feeding hole, and the method further comprises:
changing the flow of gas through the gas injector by rotating the weldment such that the edge feeding hole is aligned with one of the plurality of edge feeding passageways, and flow of gas from the edge feeding hole into the central gas feeding passageway is reduced.

10. The method of claim 1, wherein reducing the size of the guide pin includes trimming the guide pin such that the guide pin does not extend beyond a bottom edge of the holder.

11. The method of claim 1, wherein reducing the size of the guide pin includes removing the guide pin from the holder.

12. A method of processing a semiconductor substrate using a plasma processing system, the plasma processing system including a plasma chamber and a gas supply mechanism for supplying gas to the plasma chamber via a gas injector installed in a holder and a weldment installed on the gas injector, the method comprising:
placing the semiconductor substrate in the plasma chamber;
performing an etching operation on the semiconductor substrate;
monitoring an etching rate of one or more material layers deposited on the semiconductor substrate;
when a thickness of a material layer less than a threshold value,
stopping the processing of the semiconductor substrate,
removing the holder from the gas supply mechanism,
installing the holder in the gas supply mechanism, the holder including the gas injector, and
rotating the gas injector, and rotating the weldment to align an edge feeding hole of the weldment with one of a plurality of edge feeding passageways of the gas injector; and
restarting the processing of the semiconductor substrate.

13. The method of claim 12, wherein the gas injector is rotated at least 2° in a first direction, and the weldment is rotated at least 2° in a second direction opposite to the first direction.

14. The method of claim 12, further comprising
removing a guide pin of the holder after removing the holder from the gas supply mechanism.

15. The method of claim 12, wherein aligning the edge feeding hole of the weldment with one of a plurality of edge feeding passageways of the gas injector limits gas flowing through the edge feeding hole from entering a central gas feeding passageway of the gas injector.

16. The method of claim 12, wherein the weldment is rotated using a stepper motor.

17. The method of claim 12, wherein the gas injector and the weldment are rotated simultaneously.

18. The method of claim 12, wherein the gas injector and the weldment are rotated sequentially.

19. A method of operating a plasma processing system, comprising:
placing a semiconductor substrate in a plasma chamber of the plasma processing system;
introducing gas into the plasma chamber using a gas supply mechanism connected to the plasma chamber, wherein the gas supply mechanism includes
one or more sources of gas,
a holder including a gas injector, the holder having a guide pin protruding from a bottom surface thereof, the gas injector having a body that has a central gas feeding passageway and a plurality of edge feeding passageways concentrically arranged about the central gas feeding passageway and radially spaced therefrom, and the body having a flange on an outer circumferential surface of the body, the flange including a notch for receiving the guide pin,
a weldment fluidly coupled to the gas injector, the weldment including a central feeding hole and an edge feeding hole located radially separated from the central feeding hole,
etching one or more layers deposited on the semiconductor substrate;
stopping the etching;
removing the holder from the gas supply mechanism;
removing the guide pin from the holder;
installing the holder in the gas supply mechanism with the gas injector included therein;
rotating the gas injector counterclockwise;
rotating the weldment clockwise; and
resuming the etching.

20. The method of claim 19, wherein the gas injector and the weldment are rotated at least 2°.
